(19) United States
(12) Patent Application Publication
(10) Pub. No.: US 2023/0179199 A1
(43) Pub. Date: Jun. 8, 2023

(54) DRIVE CIRCUIT

(71) Applicant: KABUSHIKI KAISHA TOYOTA JIDOSHOKKI, Kariya-shi (JP)

(72) Inventors: Kazuto HIRAI, Kariya-shi (JP); Tomoyasu MOMII, Kariya-shi (JP)

(73) Assignee: KABUSHIKI KAISHA TOYOTA JIDOSHOKKI, Kariya-shi (JP)

(21) Appl. No.: 18/074,930

(22) Filed: Dec. 5, 2022

(30) Foreign Application Priority Data
Dec. 7, 2021 (JP) 2021-198627

(51) Int. Cl. H03K 17/16

(52) U.S. Cl. CPC H03K 17/162; H02M 1/08

(57) ABSTRACT

Provided is a drive circuit 1 including: a switching unit 3 including a first transistor Tr1 that constitutes an upper arm, and a second transistor Tr2 that is connected to the first transistor Tr1 in series and constitutes a lower arm; and a drive power supply 5 in which a positive electrode is connected to a gate terminal of the first transistor Tr1 and a negative electrode is connected to a source terminal of the second transistor Tr2. When turning off the switching unit 3, the first transistor Tr1 is turned off after the second transistor Tr2 is turned off

### TECHNICAL FIELD

The present disclosure relates to a drive circuit.

### BACKGROUND

In Patent Literature 1 (Japanese Unexamined Patent Publication No. 2009-136044) discloses a power MOSFET drive circuit that includes a switch drive unit and a switch control unit, and alternately turns on or off first and second power MOSFETs which are connected to each other.

When a switching element (MOSFET) is turned off, a switching loss occurs. The switching loss when being turned off is proportional to the product of a drain-source current when being turned off, a drain-source voltage after being turned off, and a turn-off operation time (off transition time). The switching loss during a turn-off operation causes heat generation or deterioration in efficiency of the switching element. According to this, in the drive circuit, a reduction in the switching loss when being turned off is required.

### SUMMARY

An object of the present disclosure is to provide a drive circuit in which a reduction in switching loss during a turn-off operation is realized.

According to an aspect of the present disclosure, there is provided a drive circuit including: a switching unit including a first switching element that constitutes an upper arm, and a second switching element that is connected to the first switching element in series and constitutes a lower arm; and a power supply in which a positive electrode is connected to a gate terminal of the first switching element and a negative electrode is connected to a source terminal or an emitter terminal of the second switching element. When turning off the switching unit, the first switching element is turned off after the second switching element is turned off.

In the drive circuit according to the aspect of the present disclosure, the first switching element and the second switching element are connected in series, and when turning off the switching unit, the first switching element is turned off after the second switching element is turned off In the drive circuit, since the second switching element is turned off first, a drain-source (collector-emitter) current when being turned off can be lowered. Accordingly, in the drive circuit, the drain-source current is lowered at an earlier stage during an entire turn-off operation of the switching unit. According to this, in the drive circuit, in the switching unit, the product of the drain-source current when being turned off, the drain-source (collector-emitter) voltage after being turned off, and the turn-off operation time can be reduced. Accordingly, in the drive circuit, a reduction in the switching loss during the turn-off operation can be realized.

The drive circuit may further include a drive unit that drives the second switching element. In this configuration, since the second switching element is independently controlled (turned on or off) by the drive unit, the first switching element can be turned off after the second switching element is turned off.

The first switching element may be an insulated gate bipolar transistor or an SiC transistor.

The drive circuit may further include a Zener diode including a cathode terminal and an anode terminal The cathode terminal of the Zener diode may be connected between the first switching element and the second switching element, and the anode terminal of the Zener diode may be connected to the source terminal or the emitter terminal of the second switching element. In this configuration, it is possible to suppress a negative voltage from increasing in the first switching element. Accordingly, it is possible to suppress failure (breakage or the like) from occurring in the first switching element.

The drive circuit may further include a diode including a cathode terminal and an anode terminal. The cathode terminal may be connected to the gate terminal of the first switching element, and the anode terminal may be connected between the first switching element and the second switching element. In this configuration, it is possible to suppress a negative voltage from increasing in the first switching element. Accordingly, it is possible to suppress failure (breakage or the like) from occurring in the first switching element.

A withstand voltage of the first switching element may be greater than a withstand voltage of the second switching element. Typically, in a switching element with a large withstand voltage, switching characteristics may deteriorate. In other words, in a switching element with a small withstand voltage, the switching characteristics are high. Accordingly, in the drive circuit, the withstand voltage of the second switching element is set to be smaller than the withstand voltage of the first switching element to enhance the switching characteristics of the second switching element. As a result, it is possible to shorten the turn-off operation time of the second switching element. According to this, in the drive circuit, since the drain-source current can be lowered at an earlier stage, a reduction in the switching loss during the turn-off operation can be realized.

The power supply may be a capacitor of a bootstrap circuit.

According to the present disclosure, a reduction in the switching loss during the turn-off operation can be realized.

### BRIEF DESCRIPTION OF THE DRAWINGS

FIG. 1 is a drive circuit diagram including a drive circuit according to a first embodiment.

FIG. 2 is a view illustrating a relationship between time, and a voltage and a current.

FIG. 3A is a view illustrating a switching loss of a drive circuit according to a comparative example, and FIG. 3B is a view illustrating a switching loss of the drive circuit according to the first embodiment.

FIG. 4 is a circuit diagram including a drive circuit according to another embodiment.

### DETAILED DESCRIPTION

Hereinafter, preferred embodiments of the invention will be described in detail with reference to the accompanying drawings. Note that, the same reference numeral will be given to the same or equivalent element in description of the drawings, and redundant description will be omitted.

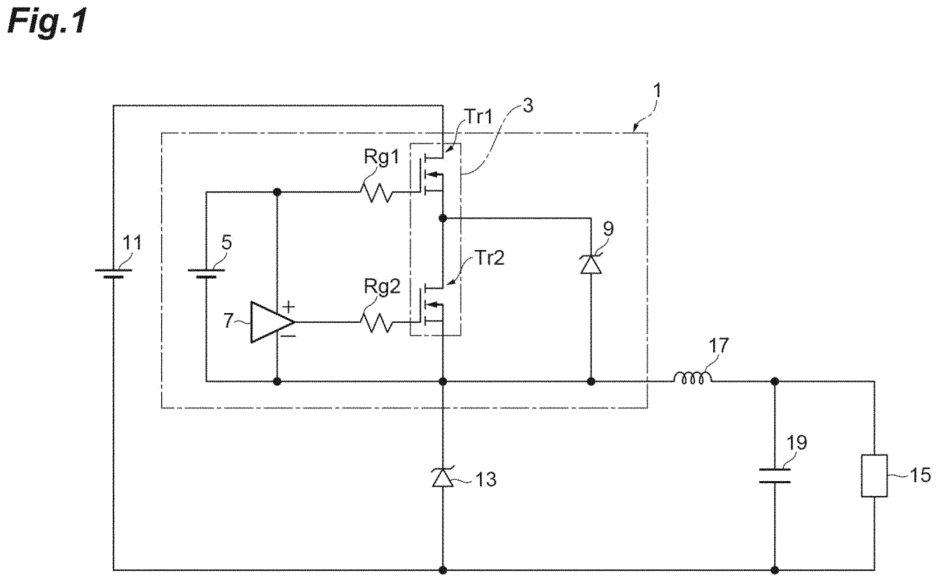

FIG. 1 is a circuit diagram including a drive circuit according to a first embodiment. As illustrated in FIG. 1, a drive circuit 1 controls driving of a load 15 that is connected to a drive power supply 11 (DC power supply). A capacitor 19 is connected to the load 15 in parallel.

The drive circuit 1 includes a switching unit 3, a drive power supply 5, a driver integrated circuit (IC) (drive unit) 7, and a Zener diode 9.

The switching unit 3 includes a first transistor Tr1 (first switching element) and a second transistor Tr2 (second switching element). The first transistor Tr1 and the second transistor Tr2 are connected in series. The first transistor Tr1 and the second transistor Tr2 are connected in series between a positive electrode and a negative electrode of the drive power supply 11.

The first transistor Tr1 constitutes a so-called upper arm in the drive circuit 1. For example, the first transistor Tr1 is an n-channel type metal-oxide-semiconductor field effect transistor (MOSFET). Specifically, the first transistor Tr1 is, for example, an SiC transistor (SiC-MOSFET). A gate resistor Rg1 is connected to a gate terminal of the first transistor Tr1. The gate resistor Rg1 may be one resistive element, or may be constituted by a plurality of resistive elements. The positive electrode of the drive power supply 11 is connected to a drain terminal of the first transistor Tr1. A drain terminal of the second transistor Tr2 is connected to a source terminal of the first transistor Tr1.

The second transistor Tr2 constitutes a so-called lower arm in the drive circuit 1. For example, the second transistor Tr2 is an n-channel type MOSFET. Specifically, the second transistor Tr2 is, for example, an Si transistor (Si-MOSFET). A gate resistor Rg2 is connected to a gate terminal of the second transistor Tr2. The gate resistor Rg2 may be one resistive element or may be constituted by a plurality of resistive elements. The drain terminal of the second transistor Tr2 is connected to the source terminal of the first transistor Tr1. The negative electrode of the drive power supply 11 is connected to a source terminal of the second transistor Tr2 through a Zener diode 13. An inductance 17 is formed between the source terminal of the second transistor Tr2 and the load 15.

In this embodiment, a withstand voltage of the first transistor Tr1 is higher than a withstand voltage of the second transistor Tr2. In other words, the withstand voltage of the second transistor Tr2 is lower than the withstand voltage of the first transistor Tr1. For example, the withstand voltage of the first transistor Tr1 is 600 V to 1000 V. For example, the withstand voltage of the second transistor Tr2 is 30 V to 50 V. A total withstand voltage of the first transistor Tr1 and the second transistor Tr2 (withstand voltage of the switching unit 3) may be equal to or greater than a voltage that is applied between the drain terminal of the first transistor Tr1 and the source terminal of the second transistor Tr2. Switching characteristics (turn-on delay time, rise time, turn-off delay time, fall time, and the like) of the second transistor Tr2 are preferably superior to switching characteristics of the first transistor Tr1. A turn-on operation and a turn-off operation of the second transistor Tr2 are faster in comparison to the first transistor Tr1.

The drive power supply 5 supplies power to the first transistor Tr1 and the driver IC 7. The drive power supply 5 is a DC power supply. For example, a voltage of the drive power supply 5 is approximately 18 V. A positive electrode of the drive power supply 5 is connected to the gate terminal of the first transistor Tr1 through the gate resistor Rg1, and a negative electrode of the drive power supply 5 is connected to the source terminal of the second transistor Tr2.

The driver IC 7 drives the second transistor Tr2. The positive electrode and the negative electrode of the drive power supply 5 are connected to the driver IC 7. An output of the driver IC 7 is connected to the gate terminal of the second transistor Tr2 through the gate resistor Rg2. The driver IC 7 controls an operation of the second transistor Tr2 on the basis of a command that is output from a control circuit (not illustrated).

A cathode terminal of the Zener diode 9 is connected between the first transistor Tr1 and the second transistor Tr2. Specifically, the cathode terminal of the Zener diode 9 is connected to the source terminal of the first transistor Tr1 and the drain terminal of the second transistor Tr2. An anode terminal of the Zener diode 9 is connected to the source terminal of the second transistor Tr2. A breakdown voltage of the Zener diode 9 is slightly higher than a drive voltage of the first transistor Tr1, and is lower than the withstand voltage of the second transistor Tr2. The Zener diode 9 clamps a voltage between the drain terminal and the source terminal of the second transistor Tr2 (drain-source voltage of the first transistor Tr1).

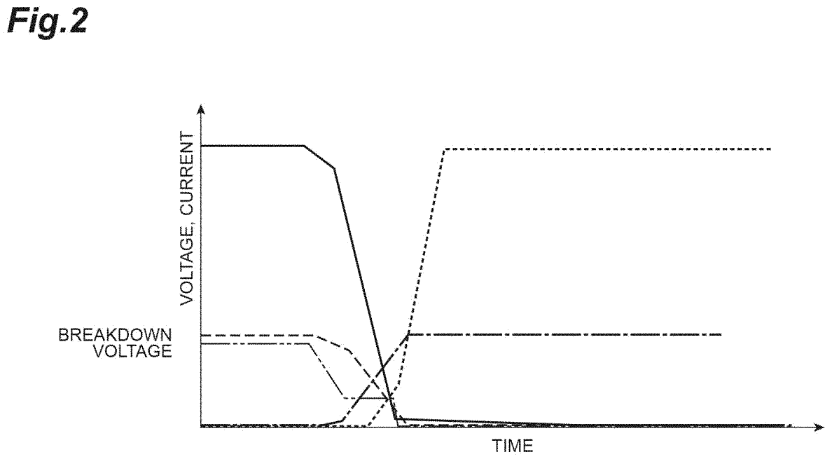

Next, an operation of the drive circuit 1 will be described with reference to FIG. 2. FIG. 2 is a view illustrating a turn-off operation of a switching unit, and illustrates characteristics of a current and a voltage with respect to time. In FIG. 2, a solid line indicates a current (drain-source current) that flows between the first transistor Tr1 (drain terminal) and the second transistor Tr2 (source terminal) in the switching unit 3. In FIG. 2, a broken line having a short line segment (hereinafter, referred to as “first broken line”) indicates a drain-source voltage of the first transistor Tr1. In FIG. 2, a broken line having a long line segment (hereinafter, referred to as “second broken line”) indicates a gate voltage of the first transistor Tr1 (voltage between the gate terminal of the first transistor Tr1 and the source terminal of the second transistor Tr2). In FIG. 2, a one-dot chain line indicates a drain-source voltage of the second transistor Tr2. In FIG. 2, a two-dot chain line indicates a gate voltage of the second transistor Tr2. In FIG. 2, a broken line parallel to the horizontal axis (time axis) indicates a breakdown voltage of the Zener diode 9.

In the drive circuit 1, in a state in which the switching unit 3 is turned on (the first transistor Tr1: ON, and the second transistor Tr2: ON), a drive voltage (for example, 18 V) is applied to the gate terminal of the first transistor Tr1 by the drive power supply 5 (the second broken line in FIG. 2), and a drive voltage (for example, 18 V) is applied to the gate terminal of the second transistor Tr2 by the driver IC 7 (the two-dot chain line in FIG. 2). At this time, a voltage between the drain terminal of the first transistor Tr1 and the drain terminal of the second transistor Tr2, and a voltage between the drain terminal of the second transistor Tr2 and the source terminal of the second transistor Tr2 become 0 V. In a state in which the switching unit 3 is turned on, as indicated by the solid line in FIG. 2, a current flows between the drain terminal of the first transistor Tr1 and the source terminal of the second transistor Tr2.

In the drive circuit 1, when turning off the switching unit 3 from the turn-on state, the first transistor Tr1 is turned off after turning off the second transistor Tr2. Specifically, in a case of turning off the switching unit 3, an off-command is output to the driver IC 7 from the control circuit, and the driver IC 7 tries to lower a gate terminal voltage of the second transistor Tr2 to 0 V through the gate resistor Rg2. According to this, as indicated by the two-dot chain line in FIG. 2, a gate voltage of the second transistor Tr2 is lowered, and the second transistor Tr2 is turned off The gate voltage of the second transistor Tr2 is lowered in a step shape, and when reaching a gate mirror voltage, the gate voltage becomes a constant value, is lowered again after passage of predetermined time, and becomes zero.

In accordance with the turn-off operation of the second transistor Tr2, as indicated by the one-dot chain line in FIG. 2, the drain-source voltage of the second transistor Tr2 rises. When the drain-source voltage of the second transistor Tr2 rises and becomes a constant voltage, as indicated by the solid line in FIG. 2, a drain-source current becomes approximately zero.

In addition, in accordance with the turn-off operation of the second transistor Tr2, as indicated by the second broken line in FIG. 2, the gate voltage of the first transistor Tr1 is lowered. In addition, as indicated by the first broken line in FIG. 2, the drain-source voltage of the first transistor Tr1 rises. According to this, the first transistor Tr1 is turned off As described above, in the switching unit 3, when the second transistor Tr2 is turned off, according to this, the first transistor Tr1 is also automatically turned off Through this operation, the switching unit 3 is turned off

As described above, in the drive circuit 1 according to this embodiment, the first transistor Tr1 and the second transistor Tr2 are connected in series, and when turning off the switching unit 3, the first transistor Tr1 is turned off after the second transistor Tr2 is turned off In the drive circuit 1, since the second transistor Tr2 is turned off first, a drain-source current when being turned off can be lowered. According to this, in the drive circuit 1, the drain-source current is lowered at an earlier stage during an entire turn-off operation of the switching unit 3. According to this, in the drive circuit 1, in the switching unit 3, the product of the drain-source current when being turned off, the drain-source voltage after being turned off, and the turn-off operation time can be reduced. Accordingly, in the drive circuit 1, a reduction in the switching loss during the turn-off operation can be realized.

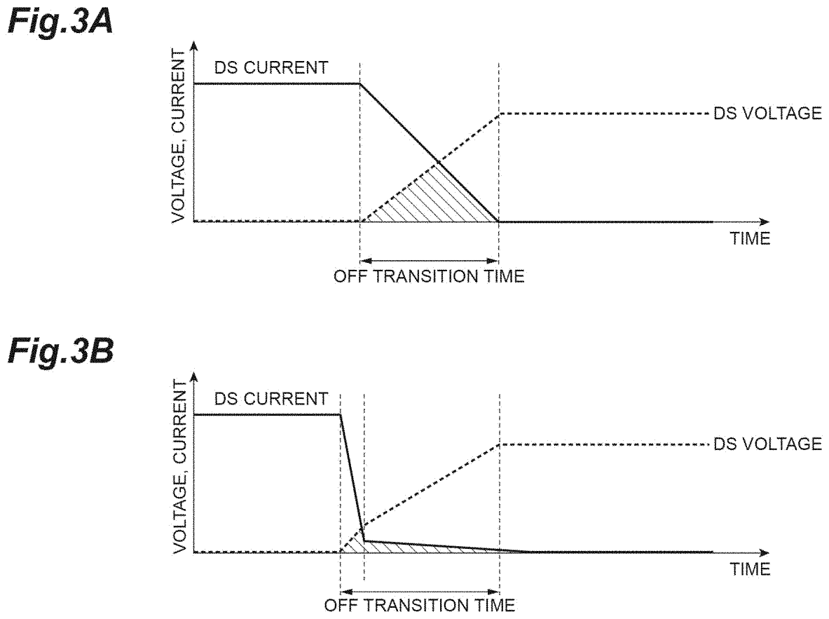

FIG. 3A is a view illustrating a switching loss of a drive circuit according to a comparative example, and FIG. 3B is a view illustrating the switching loss of the drive circuit 1 according to this embodiment. In FIGS. 3A and 3B, the switching loss is schematically illustrated. In the drive circuit according to the comparative example, one MOSFET is provided, and an operation of the MOSFET is controlled by a driver IC to which power is supplied from a driver power supply.

As illustrated in FIG. 3A, in the drive circuit according to the comparative example, as indicated by the product (an area of hatched region) of a drain-source current (DS current) when being turned off, a drain-source voltage (DS voltage) after being turned off, and turn-off operation time (off transition time), the switching loss occurs.

In the drive circuit 1 according to this embodiment, as illustrated in FIG. 3B, since the second transistor Tr2 is turned off first and the drain-source current is lowered, for the turn-off operation time (off transition time) of the switching unit 3, the drain-source current is lowered at an earlier stage. According to this, the product (area of a hatched region) of the drain-source current (DS current) when being turned off, the drain-source voltage (DS voltage) after being turned off, and the turn-off operation time (off transition time) is further reduced in comparison to the drive circuit according to the comparative example Accordingly, in the drive circuit 1, a reduction in the switching loss during the turn-off operation can be realized.

The drive circuit 1 according to this embodiment includes the driver IC 7 that drives the second transistor Tr2. In this configuration, since the second transistor Tr2 is independently controlled (turned on or off) by the driver IC 7, the first transistor Tr1 can be turned off after the second transistor Tr2 is turned off

The drive circuit 1 according to this embodiment includes the Zener diode 9 including the cathode terminal and the anode terminal In the drive circuit 1, the cathode terminal of the Zener diode 9 is connected between the first transistor Tr1 and the second transistor Tr2, and the anode terminal of the Zener diode 9 is connected to the source terminal of the second transistor Tr2. In this configuration, it is possible to suppress a negative voltage from increasing in the first transistor Tr1.

Accordingly, it is possible to suppress failure (breakage or the like) from occurring in the first transistor Tr1. Particularly, in a case where the first transistor Tr1 is an SiC-MOSFET, a withstand voltage with respect to a negative voltage is low. Accordingly, in a case where the first transistor Tr1 is the SiC-MOSFET, the Zener diode 9 is preferably provided.

In the drive circuit 1 according to this embodiment, the withstand voltage of the first transistor Tr1 is greater than the withstand voltage of the second transistor Tr2. Typically, in a transistor (MOSFET) with a large withstand voltage, switching characteristics may deteriorate. In other words, in a transistor with a small withstand voltage, the switching characteristics are high. Accordingly, in the drive circuit 1, the withstand voltage of the second transistor Tr2 is set to be smaller than the withstand voltage of the first transistor Tr1 to enhance the switching characteristics of the second transistor Tr2. As a result, it is possible to shorten the turn-off operation time of the second transistor Tr2. According to this, in the drive circuit 1, since the drain-source current can be lowered at an earlier stage, a reduction in the switching loss during the turn-off operation can be realized.

Hereinbefore, the embodiment of the invention has been described, but the invention is not limited to the above-described embodiment, and various modifications can be made within a range not departing from the gist of the invention.

In the embodiment, description has been given of an example in which the drive circuit 1 includes the Zener diode 9. However, the drive circuit 1 may not include the Zener diode 9. In this case, the withstand voltage of the second transistor Tr2 can be set to be equal to or greater than a drive voltage of the first transistor Tr1.

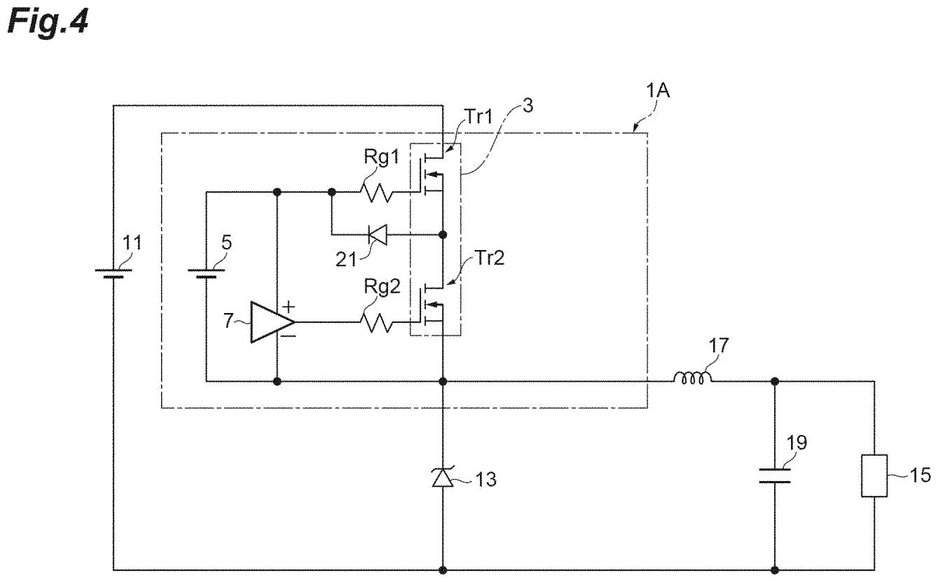

In addition, as illustrated in FIG. 4, a drive circuit 1A may include a diode 21. A cathode terminal of the diode 21 is connected to the gate terminal of the first transistor Tr1. An anode terminal of the diode 21 is connected between the first transistor Tr1 and the second transistor Tr2. Specifically, the anode terminal is connected between the source terminal of the first transistor Tr1 and the drain terminal of the second transistor Tr2. In this configuration, it is possible to suppress a negative voltage from increasing in the first transistor Tr1. Accordingly, it is possible to suppress failure (breakage or the like) from occurring in the first transistor Tr1.

In the embodiment, description has been given of an aspect in which the first transistor Tr1 is the SiC-MOSFET as an example. However, the first transistor Tr1 may be an insulated gate bipolar transistor (IGBT). In this case, “drain terminal” corresponds to “collector terminal”, and “source terminal” corresponds to “emitter terminal”

In the embodiment, description has been given of an aspect in which the second transistor Tr2 is the Si-MOSFET as an example However, the second transistor Tr2 may be another transistor.

In the embodiment, description has been given of an aspect in which the gate resistor Rg1 is connected to the gate terminal of the first transistor Tr1, and the gate resistor Rg2 is connected to the gate terminal of the second transistor Tr2 as an example However, the gate resistor Rg1 and/or the gate resistor Rg2 may not be provided.

In the embodiment, description has been given of an aspect in which the driver IC 7 is connected to the drive power supply 5 as an example. However, power may be supplied to the driver IC 7 from another power supply other than the drive power supply 5.

In the embodiment, description has been given of an aspect in which the drive power supply 5 is a DC power supply as an example. However, the drive power supply 5 may be a capacitor of a bootstrap circuit.

The drive circuit 1 according to the embodiment is applicable to an inverter and a converter.

What is claimed is:

1. A drive circuit comprising:
a switching unit including a first switching element that constitutes an upper arm, and a second switching element that is connected to the first switching element in series and constitutes a lower arm; and
a power supply in which a positive electrode is connected to a gate terminal of the first switching element and a negative electrode is connected to a source terminal or an emitter terminal of the second switching element,
wherein when turning off the switching unit, the first switching element is turned off after the second switching element is turned off

2. The drive circuit according to claim 1, further comprising:
a drive unit that drives the second switching element.

3. The drive circuit according to claim 1,
wherein the first switching element is an insulated gate bipolar transistor or an SiC transistor.

4. The drive circuit according to claim 1, further comprising:
a Zener diode including a cathode terminal and an anode terminal,
wherein the cathode terminal of the Zener diode is connected between the first switching element and the second switching element, and the anode terminal of the Zener diode is connected to the source terminal or the emitter terminal of the second switching element.

5. The drive circuit according to claim 1, further comprising:
a diode including a cathode terminal and an anode terminal,
wherein the cathode terminal is connected to the gate terminal of the first switching element, and the anode terminal is connected between the first switching element and the second switching element.

6. The drive circuit according to claim 1,
wherein a withstand voltage of the first switching element is greater than a withstand voltage of the second switching element.

7. The drive circuit according to claim 1,
wherein the power supply is a capacitor of a bootstrap circuit.
